(19) United States
(12) Patent Application Publication
(10) Pub. No.: US 2026/0344288 A1
(43) Pub. Date: Oct. 29, 2026

(54) Thermoelectric Energy Generation System Using Longitudinal and Transverse Thermopower

(71) Applicant: University Of Cincinnati, Cincinnati, OH (US)

(72) Inventors: Sarah June WATZMAN, Cincinnati, OH (US); Eleanor Frances SCOTT, Cincinnati, OH (US); Katherine Amburn SCHLAAK, Cincinnati, OH (US)

(73) Assignee: University Of Cincinnati, Cincinnati, OH (US)

(21) Appl. No.: 18/772,092

(22) Filed: Jul. 12, 2024

Related U.S. Application Data
(60) Provisional application No. 63/526,384, filed on Jul. 12, 2023.

(51) Int. Cl. H10N 10/851; H10N 15/10

(52) U.S. Cl. CPC H10N 10/851; H10N 15/15

(57) ABSTRACT

A thermoelectric device comprising a topological semimetal that includes a gapless energy band structure. A temperature gradient is applied to the topological semimetal between two opposing ends. The temperature gradient causes charge carriers to move in a first direction from the first opposing end to the second opposing end. A magnetic field is applied to the topological semimetal in a second direction. Characteristics of the gapless energy band structure cause a first portion of the charge carriers continue to move in the first direction, even in the presence of the magnetic field, while the magnetic field causes a second portion of the charge carriers to move in a third direction. The temperature gradient and a longitudinal voltage of the first portion of charge carriers create a longitudinal thermopower. The temperature gradient and a transverse voltage of the second portion of the charge carriers create a transverse thermopower.

### RELATED APPLICATIONS

This application claims priority to and benefit of U.S. Provisional Application Ser. No. 63/526,384, filed Jul. 12, 2023, which is hereby incorporated by reference in its entirety.

### STATEMENT REGARDING FEDERALLY FUNDED RESEARCH OR DEVELOPMENT

This invention was made with government support under grant number DE-SC0020154 awarded by the U.S. Department of Energy, Office of Science, Office of Basic Energy Sciences Early Career Research Program. The government has certain rights in the invention.

### TECHNICAL FIELD

The present invention relates to thermoelectric generators.

### BACKGROUND

A thermoelectric generator is a device that uses a thermoelectric material to convert heat into electricity. To generate electricity, a temperature gradient is applied to the thermoelectric material, such as by heating one side of the thermoelectric material and cooling the other. The difference in temperature between opposing sides creates electric current. The electric current is carried by tiny particles called charge carriers. The group of charge carriers present in the thermoelectric material is referred to collectively as a charge carrier system. A charge carrier system can be a single carrier system or a two carrier system. A single charge carrier system can be a negatively charged (N-type) single carrier system or a positively charged (P-type) single carrier system. A two carrier system utilizes both N-type and P-type charge carriers.

The conversion between thermal and electrical energy in thermoelectric materials and devices is characterized by thermopower, S_{abc}. In the context of thermoelectric effects, the subscript a refers to the direction of an applied thermal flux resulting in a temperature gradient (V̅ₐT). The subscript b refers to the direction of the measured electric field (E_{b}). The subscript c refers to the direction of the externally applied magnetic field if present (B_{c}).

Longitudinal thermopower refers to thermopower generated in a longitudinal direction through the Seebeck effect. The Seebeck effect occurs when a temperature gradient is applied across the thermoelectric material, causing the charge carriers to move from the hot side to the cold side. The movement of charge carriers generates an electric current across the material, and the current can then be harnessed to generate electrical power. Over time, applying the temperature gradient to the thermoelectric material causes all charge carriers to condense on the cold side of the material. As such, the contributions of oppositely charged carriers in a two carrier system effectively cancel each other out. Because of this, conventional thermoelectric materials that rely on the Seebeck effect are typically single carrier systems.

In some situations, a longitudinal thermopower may be generated using the Magneto-Seebeck effect. Longitudinal thermopower (S_{xxz}) can be generated when a temperature gradient is applied parallel to an electric field output in the presence of a perpendicularly applied magnetic field. Longitudinal thermopower (S_{xxz}) using the Magneto-Seebeck effect may be represented using the following:

$${S}_{} = \frac{{E}_{\text{?}} ( {B}_{\text{?}} )}{{∇}_{\text{?}} T} = - \frac{Δ {V}_{\text{?}} ( {B}_{\text{?}} )}{Δ {T}_{\text{?}}} \qquad Equation 1$$

$$\text{?} \text{indicates text missing or illegible when filed}$$

Transverse thermopower (S_{xyz}) may be generated through the Nernst effect. The Nernst effect occurs when a magnetic field is applied to the thermoelectric material in a direction that is perpendicular to the direction of the applied temperature gradient. This applies a Lorentz force to the moving charge carriers, leading to charge separation and the generation of an electric current. The space in the thermoelectric material that contains the moving charge carriers is often characterized as an electric field. In the electric field, charge carriers have a direction of motion that is perpendicular to both the temperature gradient and the magnetic field. When the magnetic field is applied to the thermoelectric material in a two carrier system, charge separation occurs, resulting in the contributions of oppositely signed charge carriers effectively adding together. As such, a conventional thermoelectric configuration in a two-carrier system is expected to possess a large Nernst effect. Transverse thermopower may be represented using the following:

$${S}_{\text{?}} = \frac{{E}_{\text{?}} ( {B}_{\text{?}} )}{{∇}_{\text{?}} T} = - \frac{Δ {V}_{\text{?}} ( {B}_{\text{?}} )}{Δ {T}_{\text{?}}} \frac{{L}_{\text{?}}}{{L}_{\text{?}}} \qquad Equation 2$$

$$\text{?} \text{indicates text missing or illegible when filed}$$

Conventionally, the Seebeck and Nernst effects have been applied separately to thermoelectric materials. That is to say, conventional thermoelectric materials are not used to simultaneously generate thermopower in both the longitudinal and transverse directions. In a two carrier system, the application of the magnetic field will result in charge carrier contributions counteracting each other in the longitudinal direction (e.g., the direction in which the temperature gradient is applied). This causes the longitudinal voltage generated by the Seebeck effect to be reduced due to fewer charge carriers contributing directly to the voltage along the direction of the temperature gradient. For this reason, conventional thermoelectric materials generate either longitudinal thermopower, or transverse thermopower, but do not simultaneously generate both in the same material.

It is an object of the present invention to provide a thermoelectric energy generation system that uses a topological semimetal to simultaneously generate a large longitudinal thermopower and a large transverse thermopower.

### SUMMARY

In an aspect of the invention, a thermoelectric energy generation system is provided. The thermoelectric energy generation system includes a thermoelectric device made using a topological semimetal. The thermoelectric energy generation system further includes a heat source that heats a first end of the topological semimetal. The thermoelectric energy generation system further includes a heat sink that cools a second end of the topological semimetal that opposes the first end. Heating the first end and cooling the second end results in a temperature gradient (ΔT) between the first end and the second end. The temperature gradient causes charge carriers to move in a first direction (x) from the first end to the second. The thermoelectric energy generation system further includes a magnetic field generator that applies a magnetic field (B_{z}) to the topological semimetal in a second direction (z) that is perpendicular to the first direction (x). Characteristics of the topological semimetal cause a first portion of the charge carriers continue to move in the first direction (x), even in the presence of the magnetic field (B_{z}). The magnetic field causes a second portion of the charge carriers to move in a third direction (y) that is perpendicular to the first direction (x) and to the second direction (z). The temperature gradient (ΔT) and a longitudinal voltage (ΔVₓ) of the first portion of charge carriers creates a longitudinal thermopower (S_{xxz}). The temperature gradient (ΔT) and a transverse voltage (ΔV_{y}) of the second portion of the charge carriers create a transverse thermopower (S_{xyz}).

In an embodiment of the invention, the characteristics of the topological semimetal include a gapless energy band structure that causes the first portion of the charge carriers to continue to move in the first direction (x) even in the presence of the magnetic field (B_{z}).

In another embodiment of the invention, the topological semimetal is a Weyl semimetal or a Dirac semimetal. In another embodiment of the invention, a shape of the topological semimetal is such that inverting coordinates of points in the topological semimetal does not result in an identical structure.

In another embodiment of the invention, the longitudinal voltage and the transverse voltage are created at the same or nearly the same time. In another embodiment of the invention, the longitudinal thermopower and the transverse thermopower are of the same or similar order of magnitude.

In another aspect of the invention, a thermoelectric device is provided. The thermoelectric device includes a topological semimetal that includes at least a first end and a second end that opposes the first end. The topological semimetal has a gapless energy band structure. The first end is heated and the second end is cooled. Heating the first end and cooling the second end results in a temperature gradient (ΔT) between the first end and the second end. The temperature gradient causes charge carriers to move in a first direction (x) from the first end to the second. A magnetic field (B_{z}) is applied to the topological semimetal in a second direction (z) that is perpendicular to the first direction (x). Characteristics of the gapless energy band structure cause a first portion of the charge carriers to continue to move in the first direction (x), even in the presence of the magnetic field (B_{z}). The magnetic field causes a second portion of the charge carriers to move in a third direction (y) that is perpendicular to the first direction (x) and to the second direction (z). The temperature gradient (ΔT) and a longitudinal voltage (ΔVₓ) of the first portion of charge carriers create a longitudinal thermopower (S_{xxz}). The temperature gradient (ΔT) and a transverse voltage (ΔV_{y}) of the second portion of the charge carriers create a transverse thermopower (S_{xyz}).

In an embodiment of the invention, the topological semimetal is a Weyl semimetal or a Dirac semimetal. In another embodiment of the invention, a shape of the topological semimetal is a body-centered tetragonal structure. In an embodiment of the invention, the longitudinal voltage and the transverse voltage are created at the same or nearly the same time.

In another aspect of the invention, a method for using a topological semimetal to generate a longitudinal thermopower and a transverse thermopower is provided. The method comprises heating a first end of the topological semimetal. The method further comprises cooling a second end of the topological semimetal, where the second end opposes the first end. Heating the first end and cooling the second end causes a temperature gradient (ΔT) between the first end and the second end. The method further comprises applying a magnetic field (B_{z}) to the topological semimetal in a second direction (z) that is perpendicular to the first direction (x). Characteristics of a gapless energy band structure of the topological semimetal cause a first portion of the charge carriers to continue to move in the first direction (x), even in the presence of the magnetic field (B_{z}). The magnetic field causes a second portion of the charge carriers to move in a third direction (y) that is perpendicular to the first direction (x) and to the second direction (z). The method further comprises generating, based on temperature gradient (ΔT), a longitudinal voltage (ΔVₓ) for the first portion of charge carriers. The longitudinal voltage (ΔVₓ) and the temperature gradient (ΔT) create a longitudinal thermopower (S_{xxz}). The method further comprises generating, based on temperature gradient (ΔT), a transverse voltage (ΔV_{y}) for the second portion of the charge carriers. The transverse voltage (ΔV_{y}) and the temperature gradient (ΔT) create a transverse thermopower (S_{xyz}).

In an embodiment of the invention, the topological semimetal is a Weyl semimetal or a Dirac semimetal. In another embodiment of the invention, a shape of the topological semimetal is such that inverting coordinates of points in the topological semimetal does not result in an identical structure. In an embodiment of the invention, the longitudinal voltage and the transverse voltage are created at the same or nearly the same time.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. The objects and advantages of the disclosed invention will be further appreciated in light of the following detailed descriptions and drawings in which:

FIG. 1 is an illustration showing the types of charge carrier motion that can occur in a conventional thermoelectric material.

FIG. 2 is a schematic representation of a thermoelectric energy generation system according to the principles of the present invention.

FIG. 3 is an illustration of a thermoelectric device according to the principles of the present invention, where the thermoelectric device is made using a topological semimetal and is implemented as part of the thermoelectric energy generation system to simultaneously generate a large longitudinal thermopower and a large transverse thermopower.

FIG. 4 is a diagram of a flowchart of an example process for using the topological semimetal to generate a longitudinal thermopower and a transverse thermopower.

FIGS. 5A and 5B are a pair of graphs showing the temperature dependence of the magneto-Seebeck effect, S_{xxz}, in polycrystalline NbP for Sample 1 and Sample 2 at discrete magnetic fields.

FIGS. 6A and 6B are a pair of graphs showing the magnetic field-dependence of the Nernst thermopower at discrete temperatures in Sample 1 and Sample 2.

FIGS. 7A-7D are a set of graphs showing the temperature-dependence of zT and PF in Sample 1 and Sample 2 with certain contributions from the Seebeck effect, magneto-Seebeck effect and Nernst effect, and certain combined longitudinal and transverse effects for the proposed device.

### DETAILED DESCRIPTION

The following detailed description of example embodiments refers to the accompanying drawings. The same reference numbers in different drawings may identify the same or similar elements.

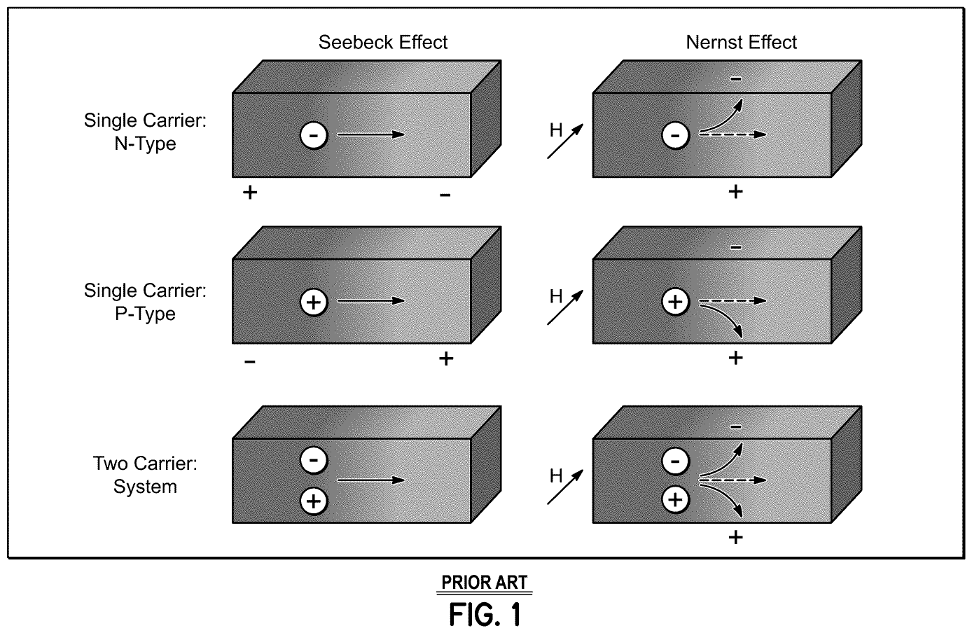

FIG. 1 is an illustration showing the types of charge carrier motion that can occur in a conventional thermoelectric material. The left side of FIG. 1 shows the thermoelectric material utilizing the Seebeck effect in a negatively charged (N-type) single carrier system, a positively charged (P-type) single carrier system, and a two carrier system that uses both N-type and P-type charge carriers. The right side of FIG. 1 shows the thermoelectric material utilizing the Nernst effect in the N-type single carrier system, the P-type single carrier system, and the two carrier system.

As can be seen in FIG. 1, the thermoelectric material is colored to represent a thermal gradient (sometimes referred to herein as a temperature gradient) applied to the material. The color red indicates the side of the thermoelectric material that is heated and the color blue indicates the side of the thermoelectric material that is cooled. The thermal gradient represents a change in temperature throughout the material. The circular objects shown with positive and negative signs are charge carriers. The arrows next to the charge carriers reflect the direction of motion of the carriers. The arrow H indicates the direction of the externally applied magnetic field, which is constant.

As described above, the illustrated charge carrier motion demonstrates that, conventionally, single carrier systems are better suited for use in the longitudinal geometry while two carrier systems are better suited for use in the transverse geometry. For example, under the Seebeck effect, all charge carriers condense on the cold side of the material, making it such that the contributions of oppositely charged carriers effectively cancel each other out. Because of this, conventional thermoelectric materials that use the Seebeck effect are typically single carrier systems. Under the Nernst effect, the application of the magnetic field will result in charge carrier contributions counteracting each other in the longitudinal direction (e.g., the direction in which the temperature gradient is applied). This causes the longitudinal voltage generated by the Seebeck effect to be reduced due to fewer charge carriers contributing directly to the voltage along the direction of the temperature gradient. For this reason, conventional thermoelectric materials that use the Nernst effect are implemented as two carrier systems.

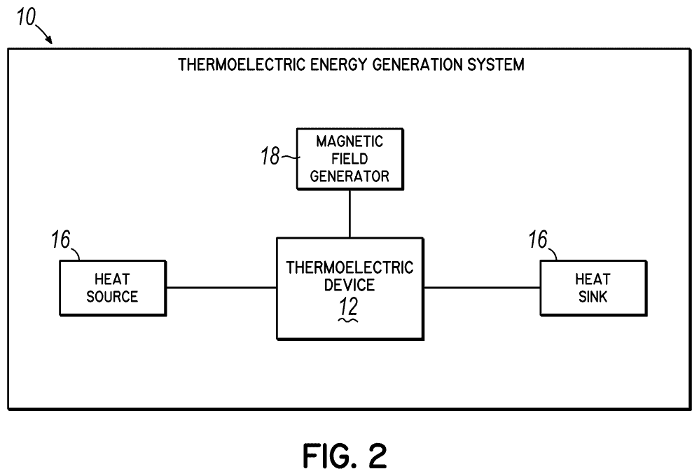

FIG. 2 is a schematic representation of a thermoelectric energy generation system 10 according to the principles of the present invention. The thermoelectric energy generation system 10 includes one or more devices and/or components capable of being used to generate longitudinal and/or transverse thermopower. For example, the thermoelectric energy generation system 10 may include a thermoelectric device 12, a heat source 14, a heat sink 16, and a magnetic field generator 18.

Thermoelectric device 12 is made using a topological semimetal and is capable of being used to generate thermopower in multiple directions. For example, the thermoelectric device 12 is made using a topological semimetal such as a Weyl semimetal, a Dirac semimetal, a nodal line semimetal, and/or another type of semimetal. Topological semimetals are materials that include important properties for generating both longitudinal and transverse thermopower. Notably, topological semimetals have a gapless band structure. In most materials, conduction and valance bands are separated by a band (energy) gap. Electrons need enough energy to traverse from the valance band to the conduction band for electrical conduction to occur, and as a result, the band gap limits the potential thermopower of the device. However, topological semimetals have a gapless band structure where the conduction and valence bands touch at certain points (e.g., Weyl nodes, Dirac nodes, etc.). This results in having charge carriers with ultra-high mobility, thereby allowing for a large longitudinal thermopower despite the presence of the magnetic field.

In a preferred embodiment, the topological semimetal is a Weyl semimetal. For example, the topological semimetal may include NbP, such as a single crystalline NbP or a polycrystalline NbP, CO₃Sn₂S₂, Tantalum Arsenide (TaAs), Tantalum Phosphide (TaP), Molybdenum Ditelluride (MoTe₂), an alloyed version of MoTe₂ (e.g., Mo_{0.92}Nb_{0.08} Te₂), YbMnBi₂, or another type of Weyl semimetal. In some embodiments, the topological semimetal may be a Dirac semimetal, such as graphene, topological insulators, and/or the like.

Heat source 14 includes one or more devices capable of heating an end of the thermoelectric device 12. For example, the heat source 14 may include a resistive heater, a Peltier device, a hot plate, a laser heater, a combustion source, and/or any other type of heat source known in the art.

Heat sink 16 includes one or more devices capable of cooling an end of the thermoelectric device 12. For example, the heat sink 16 may include a water-cooling system, a Peltier device, an air-cooling system, a cryogenic cooler, and/or any other device or apparatus made using material with high thermal conductivity.

Magnetic field generator 18 includes magnets and/or devices capable of generating a magnetic field. For example, the magnetic field generator 18 may include one or more permanent magnets, one or more electromagnets (e.g., which could be externally powered to provide a tunable magnetic field), and/or any other magnets or devices capable of generating the magnetic field.

In some embodiments, the thermoelectric device 12, the heat source 14, the heat sink 16, and/or the magnetic field generator 18 may be part of the thermoelectric energy generation system 10. In some embodiments, the thermoelectric device 12, the heat source 14, the heat sink 16, and/or the magnetic field generator 18 may be a separate external device.

The number and arrangement of devices and/or networks shown in FIG. 2 are provided as an example. In practice, there may be additional devices and/or networks, fewer devices and/or networks, different devices and/or networks, or differently arranged devices and/or networks than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) of FIG. 2 may perform one or more functions described as being performed by another set of devices of FIG. 2.

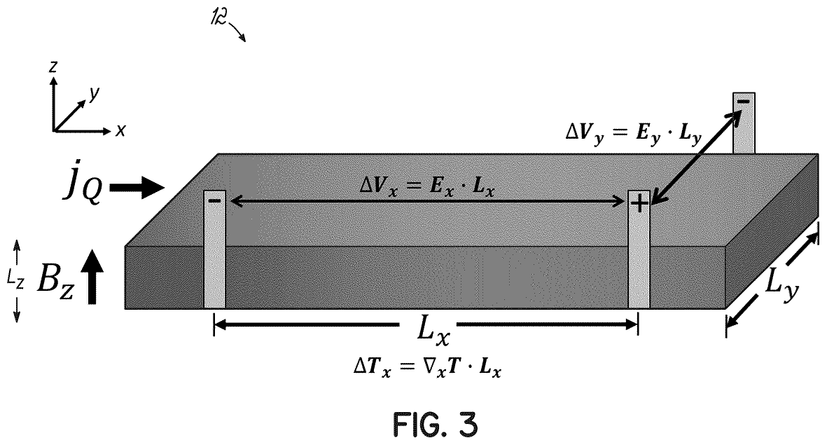

FIG. 3 is an illustration of a thermoelectric device 12 according to the principles of the present invention, where the thermoelectric device 12 is made using a topological semimetal and implemented as part of the thermoelectric energy generation system 10 to simultaneously generate large longitudinal and transverse thermopower. For example, the thermoelectric device 12 may be implemented as part of the thermoelectric energy generation system 10 and may be made using a topological semimetal that has characteristics that are able to take advantage of both the magneto-Seebeck and Nernst effects. As described above, the topological semimetal may be a topological semimetal, such as a Weyl semimetal, a Dirac semimetal, and/or another type of semimetal.

In a preferred embodiment, the thermoelectric device 12 is made using a Weyl semimetal. Weyl semimetals have a gapless band structure that enables ultra-high charge carrier mobility. Comparatively, in most materials, conduction and valance bands are separated by a band (energy) gap. Electrons need enough energy to traverse from the valance band to the conduction band for electrical conduction to occur, and as a result, the band gap limits the potential thermopower of the device. However, Weyl semimetals have a gapless band structure where the conduction and valence bands touch at certain points (e.g., Weyl nodes). This results in topological semimetals having charge carriers with ultra-high mobility.

In some embodiments, the thermoelectric device 12 is made using a Dirac semimetal. Dirac semimetals have a gapless band structure where the conduction and valence bands meet at Dirac points, where the band crossing is protected by time-reversal and inversion symmetry. This also results in Dirac semimetals having charge carriers with high mobility and unique relativistic behavior akin to Dirac fermions.

In some embodiments, the thermoelectric device 12 may be adapted to receive metal contacts and electrodes. Metal contacts and electrodes may connect the n-type and p-type regions of the thermoelectric device 12. These can be seen in FIG. 3 as the gray pillar-shaped regions around the topological semimetal.

In FIG. 3, the thermoelectric device 12 is shown as having a length (Lₓ), a width (L_{y}), and a height (L_{z}). As shown, the left hand side of the topological semimetal is being heated by the heat source 14 and the right hand side of the topological semimetal is being heated by the heat sink 16. This causes heat to transfer from the heated end to the cooled end in a first direction (x) (e.g., in a longitudinal direction). The variable jQ, which is shown in FIG. 3 with a directional arrow pointing in the first direction (x), represents the direction and magnitude of the heat transfer through the topological semimetal. This type of heat transfer is known as a thermal flux, and results in a temperature gradient (VT) extending along the length (Lₓ) of the topological semimetal. The temperature gradient (VT) can be seen in FIG. 3, where the thermoelectric device 12 has varied amounts of shading between the heated and cooled ends of the thermoelectric device 12.

While the opposing ends are being heated and cooled, the magnetic field generator 18 may apply a magnetic field (B_{z}) to the topological semimetal in a second direction (z) that is perpendicular to the first direction (x). As can be seen in FIG. 3, the direction of the applied magnetic field (B_{z}) is perpendicular to the first direction (x), and in this particular device orientation, is a direction moving parallel with the height (L_{z}) of the topological semimetal.

Heating and cooling the opposing ends of the thermoelectric device 12 and applying the magnetic field (B_{z}) cause the topological semimetal to generate: (1) a first electric field (Eₓ) that occupies a space containing a first set of charge carriers moving along the topological semimetal in the longitudinal direction (x), and (2) a second electric field that occupies a space containing a second set of charge carriers moving along the topological semimetal in a third direction (y). The third direction (y) is often referred to as a transverse direction and is perpendicular to both the first and second directions.

The first set of charge carriers, when taken in the first (longitudinal) direction (x), has a first voltage differential (ΔVₓ) (sometimes referred to herein as a longitudinal voltage). The first voltage differential (ΔVₓ) and the temperature gradient (ΔT) create a longitudinal thermopower (S_{xxz}). Notably, due to the unique characteristics of the topological semimetal (e.g., the gapless energy bands) and/or the geometry of the topological semimetal 12, a large longitudinal thermopower (S_{xxz}) may be created despite the presence of the magnetic field (B_{z}). The second set of charge carriers, when taken in the third (transverse) direction (y), has a second voltage differential (ΔV_{y}) (sometimes referred to herein as a transverse voltage). The second voltage differential (ΔV_{y}) and the temperature gradient (ΔT) create a transverse thermopower (S_{xyz}).

In this way, the thermoelectric energy generation system 10 (e.g., using the thermoelectric device 12) simultaneously creates a longitudinal and a transverse thermopower using a single material such as a topological semimetal 12. As used herein, the term “simultaneously” is to refer to generating the respective thermopowers at the same or near the same time. Comparatively, certain conventional thermoelectric devices could potentially generate a longitudinal voltage at a first time period, and generate a transverse voltage at a second time period, such as by only applying the magnetic field during the second time period. Instead, the claimed invention creates both the longitudinal and transverse thermopowers at the same (or nearly the same) time. This allows for two different thermopowers to be created at the same time, providing faster access to the converted energy and making the converted energy more accessible for immediate use. Furthermore, generating the thermopowers at the same time improves the thermoelectric figure of merit (zT) of the topological material, where the zT measures a combined output voltage or the combined longitudinal and transverse thermopower.

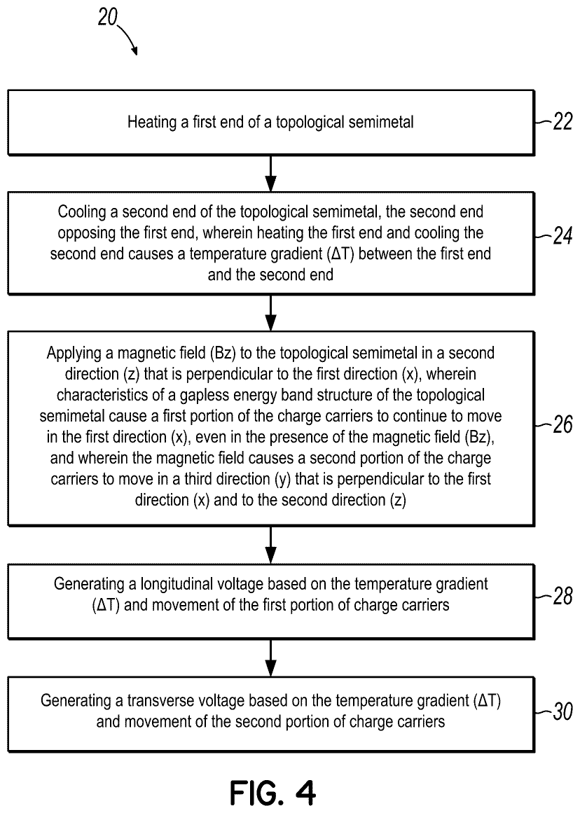

FIG. 4 is a diagram of a flowchart of an example process 20 for using the topological semimetal 12 to generate a longitudinal thermopower and a transverse thermopower. As shown by reference number 22, process 20 includes heating a first end of the topological semimetal 12. For example, the heating source 14 may heat the first end of the topological semimetal 12.

As shown by reference number 24, process 20 further includes cooling a second end of the topological semimetal, where heating the first end and cooling the second end causes a temperature gradient (ΔT) between the two ends. For example, the heat sink 16 may cool the second end of the topological semimetal 12. The second end may oppose (e.g., be positioned on an opposite side of) the first end. Heating the first end and cooling the second end causes a temperature gradient (ΔT) between the two opposing ends.

As shown by reference number 26, process 20 further includes applying a magnetic field (B_{z}) to the topological semimetal in a second direction (z) that is perpendicular to the first direction (x), wherein characteristics of a gapless energy band structure of the topological semimetal cause a first portion of the charge carriers to continue to move in the first direction (x), even in the presence of the magnetic field (B_{z}), and wherein the magnetic field causes a second portion of the charge carriers to move in a third direction (y) that is perpendicular to the first direction (x) and to the second direction (z). For example, the magnetic field generator 18 may apply a magnetic field (B_{z}) to the topological semimetal in a second direction (z) that is perpendicular to the first direction (x). Characteristics of a gapless energy band structure of the topological semimetal may cause a first portion of the charge carriers to continue to move in the first direction (x), even in the presence of the magnetic field (B_{z}). The magnetic field may cause a second portion of the charge carriers to move in a third direction (y) that is perpendicular to the first direction (x) and to the second direction (z).

As shown by reference number 28, process 20 further includes generating, based on the temperature gradient (ΔT), a longitudinal voltage (ΔVₓ) for the first portion of charge carriers moving in the first direction (x). For example, the topological semimetal 12 may generate, based on the temperature gradient (ΔT), the longitudinal voltage (ΔVₓ) for the first portion of charge carriers moving in the first direction (x). Furthermore, the temperature gradient (ΔT) and the longitudinal voltage (ΔVₓ) create a longitudinal thermopower (S_{xxz}). As noted herein, a large longitudinal thermopower (S_{xxz}) is generated even in the presence of the magnetic field (B_{z}). This is due to the topological semimetal having a gapless band structure.

As shown by reference number 30, process 20 further includes generating, based on the temperature gradient (ΔT), a transverse voltage (ΔV_{y}) for the second portion of charge carriers moving in the second direction (y). For example, the topological semimetal 12 may generate, based on the temperature gradient (ΔT), the transverse voltage (ΔV_{y}) a transverse voltage (ΔV_{y}) for the second portion of charge carriers moving in the second direction (y). Furthermore, the temperature gradient (ΔT) and the transverse voltage (ΔV_{y}) create a transverse thermopower (S_{xyz}).

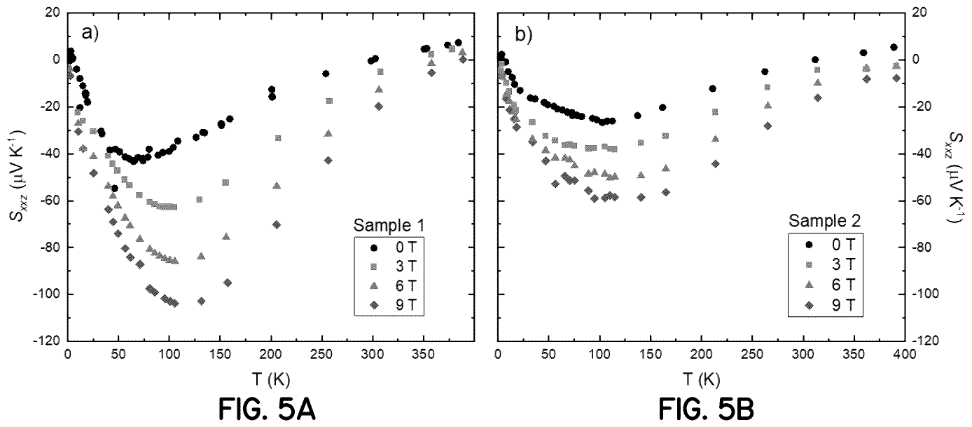

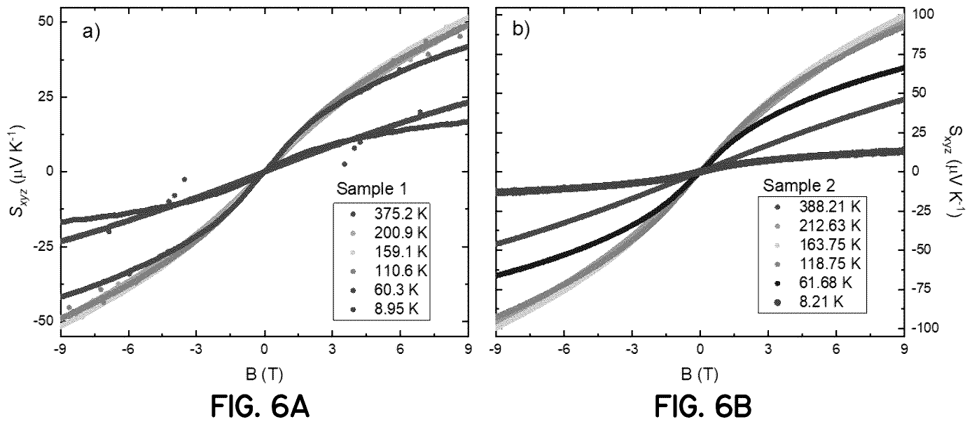

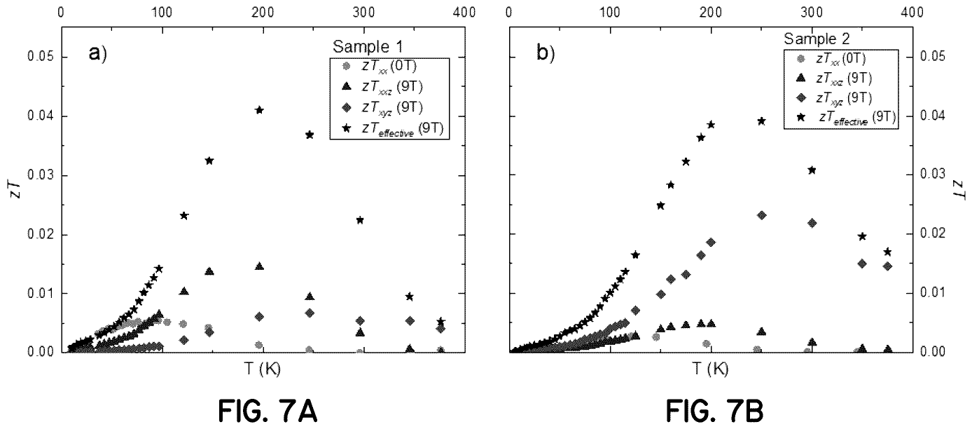

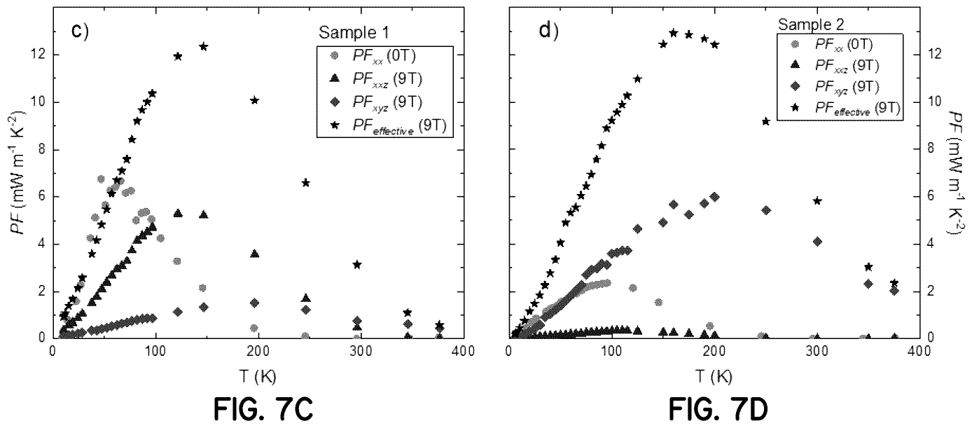

The discussion that follows is a description of FIGS. 5A and 5B, 6A and 6B, and 7A-7D, and provides additional information about concepts relating to these figures and/or concepts relating to the present invention. FIGS. 5A and 5B are a pair of graphs showing the temperature dependence of the magneto-Seebeck effect, S_{xxz}, in polycrystalline NbP for Sample 1 and Sample 2 at discrete magnetic fields. FIGS. 6A and 6B are a pair of graphs showing the magnetic field-dependence of the Nernst thermopower at discrete temperatures in Sample 1 and Sample 2. FIGS. 7A-7D are a set of graphs showing the temperature-dependence of zT and PF in Sample 1 and Sample 2 with certain contributions from the Seebeck effect, magneto-Seebeck effect and Nernst effect, and certain combined longitudinal and transverse effects for the proposed device.

The thermoelectric figure of merit (zT) is a crucial parameter for evaluating the performance of thermoelectric materials. If longitudinal and transverse thermoelectric effects are considered separately, then zT is calculated differently depending on the geometry of the thermoelectric transport property used (S_{xxz} or S_{xyz}). Equations 3 and 4 demonstrate calculating the figure of merit based on the magneto-Seebeck effect and the Nernst effect, respectively:

$${zT}_{\text{?}} = \frac{{S}_{\text{?}}^{2} {σ}_{\text{?}}}{{κ}_{\text{?}}} T \qquad Equation 3$$

$${zT}_{\text{?}} = \frac{{S}_{\text{?}}^{2} {σ}_{\text{?}}}{{κ}_{\text{?}}} T \qquad Equation 4$$

$$\text{?} \text{indicates text missing or illegible when filed}$$

In equations 3 and 4, σ represents the electrical conductivity and K represents the thermal conductivity using the subscript indices as previously described. In some embodiments, such as those using the topological semimetal shown in FIG. 3, longitudinal thermopower (S_{xxz}) and transverse thermopower (S_{xyz}) are to be used simultaneously in order to significantly enhance zT. An effective figure of merit can be defined using the combined voltage outputs, and thus the combined thermopowers, from the longitudinal and transverse thermoelectric effects (assuming σ^{xxz}≈σ^{vyz}, which is reasonable in a polycrystalline Weyl semimetal (WSM):

$${zT}_{\text{?}} = \frac{{( {S}_{\text{?}} + {S}_{\text{?}} )}^{2} {σ}_{\text{?}}}{{κ}_{\text{?}}} T \qquad Equation 5$$

$$\text{?} \text{indicates text missing or illegible when filed}$$

When both S_{xxz} and S_{xyz} are similar in magnitude, as is reasonably the case in a polycrystalline WSM, the zT_{effective} can be seen to be approximately four times greater than either zT_{xxz} or zT_{xyz} taken independently, offering a pathway towards greatly enhancing zT without altering the thermoelectric semimetal itself.

In some embodiments, the topological material may be a Weyl semimetal. For example, the topological material may be a Polycrystalline NbP. The discussion that follows discloses findings relating to Polycrystalline NbP samples. The polycrystalline NbP samples were synthesized via direct reaction using powders of niobium and phosphorus. NbP powder was formed into a solid ingot using spark plasma sintering, with approximate density of 90%. Two separate bar-shaped samples were cut from the sintered ingot to be used in transport measurements. Two bars of NbP were selected for analysis: Sample 1 was left unannealed, and Sample 2 was annealed at 1000 °C for 1 week as shown in Table 1. Sample 2 was wrapped in Nb foil with excess NbP powder then encapsulated in a quartz tube in an argon environment for annealing.

TABLE 1
NbP polycrystalline sample details

| | Average | |
|---|---|---|
| NbP Sample | Grain Size | Anneal Temperature, Time |
| Sample 1 | 2.07 μm | — |
| Sample 2 | 3.01 μm | 1000 °C, 1 week |

All transport measurements were completed on a 9 T Quantum Design DynaCool Physical Property Measurement System (PPMS). The thermal conductivity, electrical resistivity, Seebeck effect, and Nernst effect were measured using the Thermal Transport Option (TTO) in the conventional one-heater two-thermometer configuration. Resistivity and thermal conductivity were measured using MultiVu, Quantum Design's proprietary software for the PPMS. Both the Seebeck effect and Nernst effect were characterized using a home-built electrical breakout system with external electronics and customized controls code written in Labview. The magneto-Seebeck effect was characterized in both steady-state and sweeping magnetic fields, while the Nernst effect was characterized in a sweeping magnetic field. The Hall effect was measured using the PPMS's Electrical Transport Option (ETO) using the van der Pauw method. Thermoelectric transport data for both the Seebeck and Nernst effects presented in this work is isothermal.

A large magneto-Seebeck effect, S_{xxz}, was observed in both Samples 1 and 2, shown as a function of temperature at discrete magnetic fields in FIGS. 5A and 5B. S_{xxz} increased in magnitude as a function of magnetic field up to 9 T, more than doubling the maximum thermopower in comparison to the 0 T results. A maximum thermopower of 104 μV K⁻¹ at 103 K, 9 T was observed in Sample 1, and a maximum thermopower of 59.1 mV K⁻¹ at 95 K, 9 T was observed in Sample 2. Once again, the maximum values of S_{xxz} differ between the samples, and the temperature at which the maximum occurs increases with an increase in externally applied magnetic field for Sample 1. Most notable, though, is the presence of the large isothermal magneto-Seebeck effect in the polycrystalline NbP samples studied in this work as previous work in single-crystalline NbP observed no measurable isothermal magneto-Seebeck effect. Although an adiabatic magnetic-Seebeck effect was observed and attributed to parasitic contributions from the Nernst effect into the magneto-Seebeck effect; only adiabatic results for the magneto-Seebeck effect have been previously reported in polycrystalline NbP.

FIGS. 6A and 6B are a pair of graphs showing magnetic field-dependence of the Nernst thermopower at discrete temperatures in (a) Sample 1 and (b) Sample 2. The Nernst thermopower S_{xyz} in both Samples 1 and 2, shown as a function of magnetic field at a select temperature in FIGS. 6A and 6B, was found to be on the same order of magnitude as the magneto-Seebeck thermopower S_{xyz} in Samples 1 and 2, demonstrating that, although S_{xyz} is large in polycrystalline NbP it is reduced by at least an order of magnitude from the huge Nernst thermopower observed in single-crystalline NbP. Sample 1 has a maximum Nernst thermopower of 51.6 μV K⁻¹ at 159.1 K, 9 T, while Sample 2 has a maximum Nernst thermopower of 99.39 uV K⁻¹, at 163.75 K, 9 T. Both the magnitudes of the Nernst thermopower and the temperature at which they occur differ between the two samples. The Nernst thermopower as a function of magnetic field also exhibits two distinct slopes, a high field region between 13 Tl and 19 Tl and a low field region below 12 Tl, behavior which is consistent with previously work in NbP.

By calculating the thermoelectric figure of merit, zT, and power factor, PF, the performance enhancement of such a device can be quantified. Calculating zT may differ depending on the geometry of the thermoelectric transport property used. Because both the magneto-Seebeck and Nernst effects are being utilized, two different zTs and PFs can be calculated. Equations 6 and 7 are the formulae used for calculating longitudinal zT and PF, respectively, from the longitudinal thermopower S_{xxz}:

$$z {T}_{x x z} = \frac{{S}_{xxz}^{2} {σ}_{x x z}}{{κ}_{x x z}} \qquad Equation 6$$

$$P {F}_{x x z} = {S}_{x x z}^{2} {σ}_{x x z} \qquad Equation 7$$

Similarly, the method for calculating transverse zT and PF is shown in Equations 8 and 9, respectively, using the transverse thermopower Sxyz:

$$z {T}_{x y z} = \frac{{S}_{xyz}^{2} {σ}_{y y z}}{{κ}_{x x z}} \qquad Equation 8$$

$$P {F}_{x y z} = {S}_{x y z}^{2} {σ}_{y y z} \qquad Equation 9$$

It should be noted that electrical resistivity ρ, which was directly measured, is not mathematically the direct inverse of electrical conductivity σ but a tensor making

$${σ}_{x x z} = \frac{{ρ}_{xxz}}{{ρ}_{xxz}^{2} + {ρ}_{xyz}^{2}} .$$

However, because the Hall resistivity ρ_{xyz} is significantly smaller than the longitudinal electrical resistivity ρ_{xxz},

$${σ}_{x x z} \approx \frac{1}{{ρ}_{xxz}} .$$

Also, because the samples are polycrystalline, it can reasonably be assumed that the resistivity and thermal conductivity of the samples are isotropic. Therefore ρ_{xxz}=β_{yyz} and κ_{xxz}=κ_{yyz}.

We now define the effective zT and PF produced by the combined use of Nernst and magneto-Seebeck effects using Equations 10 and 11, respectively:

$$z {T}_{effective} = \frac{{( {S}_{x y z} + {S}_{x x z} )}^{2} {σ}_{x x z}}{{κ}_{x x z}} \qquad Equation 10$$

$$P {F}_{effective} = {( {S}_{x y z} + {S}_{x x z} )}^{2} {σ}_{x x z} \qquad Equation 11$$

Equations 10 and 11 refer to the zT_{effective} and PF_{effective} for the thermoelectric device 12 that is shown in FIG. 2, where device 12 is a single-legged device. However, because a conventional thermoelectric device requires two legs (n-type and p-type pair) (e.g., to achieve a transverse thermopower), the actual effective thermopower of the device would be the sum of S_{xxz} and S_{xyz} from each of the legs. Thus, both a transverse and longitudinal voltage would come from both the n-type and p-type legs in a two-legged device.

The resulting zT and PF values of Samples 1 and 2 from Equations 6-11 are shown in FIGS. 5A and 5B. In FIGS. 5A and 5B, zT_{xxz} and PF_{xxz} refer to the longitudinal figure of merit and power factor calculated from the Seebeck effect (Equations 6 and 7), and zT_{xyz} and PF_{xyz} refer to figure of merit and power factor calculated from the Nernst effect (Equations 8 and 9).

When considering all three independent thermoelectric effects observed in this work for Sample 1, zT_{xxz} (9 T) has the largest magnitude of 0.0145 at 196 K, which reflects the large magneto-Seebeck effect observed in this material. PFxx (0 T) reached the largest magnitude of 6.7 mW m⁻¹ K⁻² at 47 K. Unfortunately, this power factor is only maintained up to 200 K and drops off to near zero at higher temperatures. However, PF_{xxz} (9 T) reaches a lower maximum of 5.25 mW m⁻¹ K⁻² at 121 K, but the power factor does not start to approach zero until 300 K and higher temperatures.

Of the independent thermoelectric effects observed in Sample 2, zT_{xyz} (9 T) has the largest magnitude of 0.023 at 205 K, which reflects the larger Nernst effect observed in this sample. PF_{xyz} (9 T) reached the largest magnitude of 6.00 mW m⁻¹ K⁻² at 200 K. This power factor is also maintained from around 125 K and drops off near 300 K.

When utilizing both the magneto-Seebeck and Nernst effects simultaneously, the effective thermopower is increased in the proposed device (e.g., thermoelectric device 12) while maintaining the same resistivity and thermal conductivity. This results in zT_{effective} (9 T) reaching a maximum of 0.041 at 196 K, which is nearly triple in value as compared to the highest figure of merit for an independent thermoelectric effect in Sample 1. Similarly, PF_{effective} (9 T) reaches a maximum of 12.35 mW m⁻¹ K⁻² at 146.5 K, nearly double the maximum of power factor for an independent thermoelectric effect in Sample 1, and the large power factor is maintained across a large temperature range of approximately 100 K to 200 K.

The ZT_{effective} (9 T) of Sample 2 reaching a maximum of 0.039 at 250 K, which is not significantly different to the Sample 1 maximum, however it occurs at a much higher temperature. Sample 2's PF_{effective} (9 T) reaches a maximum of 12.91 mW m⁻¹ K⁻² at 160 K. Once again, the magnitude does not vary significantly from that of Sample 1, but the temperature at which it occurs has changed. This indicates that tuning the operating temperature of the device by means of tuning TF via doping will not significantly affect the magnitude of zT or PF of the device.

The ZT_{effective} (9 T) found here for the proposed device is competitive with, and even exceeds, figures of merit found in recent works on thermoelectric transport in WSMs. Table 3 shows the largest zT reported experimentally for other WSMs, where the maximum zT observed by a single thermoelectric effect (either Seebeck, magneto-Seebeck, or Nernst effect independently) is zT_{xyz} (9 T)=0.042 at 76 K in Mo_{0.92}Nb_{0.08}Te₂, which is comparable to the ZT_{effective} of the NbP samples in this work. Similar to the results for polycrystalline NbP reported in this work, MoTe₂ demonstrates significant changes in the maximum zT and temperature at which that maximum occurs-zT_{xyz} (9 T)=0.00297 at 19.3 K for MoTe₂ and zT_{xyz} (9 T)=0.042 at 76.1 K for Mo_{0.92}Nb_{0.08}Te₂ offering further evidence that doping can be used as a tuning mechanism to increase zT.

TABLE 3
Comparison of zT values from independent thermoelectric effects in WSMs:

| Material | Sample Type | Max zT | Conditions | Reference |
|---|---|---|---|---|
| NbP, Sample 1 | Polycrystalline | 0.0055 | zT [symbol] , (0 T), 95.70 K | this work |
| NbP, Sample 1 | Polycrystalline | 0.0145 | zT [symbol] , (9 T), 196.4 K | this work |
| NbP, Sample 1 | Polycrystalline | 0.0068 | zT [symbol] , (9 T), 2462 K | this work |
| NbP, Sample 1 | Polycrystalline | 0.041 | zT [symbol] , (9 T), 1964 K | this work |
| NbP, Sample 2 | Polycrystalline | 0.0027 | zT [symbol] , (0 T), 125.01 K | this work |
| NbP, Sample 2 | Polycrystalline | 0.0047 | zT [symbol] , (9 T), 200.01 K | this work |
| NbP, Sample 2 | Polycrystalline | 0.023 | zT [symbol] , (9 T), 250.01 K | this work |
| NbP, Sample 2 | Polycrystalline | 0.039 | zT [symbol] , (9 T), 250.01 K | this work |
| NbP | Polycrystalline | 0.0090 | zT [symbol] , (9 T), 137.4 K | |
| Co [symbol] Sn [symbol] S [symbol] | Single Crystal | 0.0221 | zT [symbol] , (0 T), 180 K | |
| TaAs | Single Crystal | 0.0133 | zT [symbol] , (0 T), 216.5 K | |
| TaP | Single Crystal | 0.003232 | zT [symbol] , (0 T), ~75 K | |
| MoTe [symbol] | Single Crystal | 0.00297 | zT [symbol] , (9 T), 19.3 K | |
| Mo [symbol] Nb [symbol] Te₂ | Single Crystal | 0.042 | zT [symbol] , (9 T), 76.1 K | |
| | (doped) | | | |
| YbMnBi₂ | Single Crystal | 0.003252 | zT [symbol] , (2 T), 183 K | |

[symbol]

indicates data missing or illegible when filed

As such, the proposed device design offers a pathway to make polycrystalline WSMs competitive for magnetic thermoelectric device applications. Worthy of note is that the majority of thermoelectric transport literature focuses on single-crystalline samples. Because this work shows a significant difference between the transport properties of polycrystalline NbP compared to single-crystalline NbP, most notably a large isothermal magneto-Seebeck effect present only in polycrystalline samples, there may be potential for thermoelectric applications in the other WSMs shown in Table 3 in their polycrystalline form.

Certain experimental and theoretical findings indicate that the thermoelectric properties of NbP are incredibly sensitive to changes in TF and thus EF, as thermoelectric transport is strongly dependent on the chemical potential's motion relative to the energy of the Weyl points. This sensitivity implies the possibility of tuning Er of NbP and other Type I WSMs to optimize thermoelectric properties at desirable operating conditions for devices. Referring now to the topological semimetal 12 and FIGS. 7A-7D, maximizing the sum of S_{xxz} and S_{xyz} at the same temperature and magnetic field (i.e., using the same temperature gradient and the same magnetic field for each thermopower) is desirable for ultimately maximizing zT_{effective}. This can be achieved by tuning TF in a material to where the maximum sum of the thermopowers is observed based on desired device operating conditions of temperature and magnetic field.

The thermoelectric properties of WSMs have recently been investigated more intensely as they offer insight into fundamental topological transport, but WSMs also demonstrate promise as thermoelectric materials themselves. Single crystals are typically seen to have the most impressive thermoelectric transport properties; however, single crystals are also costly, difficult to synthesize, and typically small and fragile. If WSMs are to be used in practical applications, polycrystalline samples are the cheaper and more durable option. Here, we find a simultaneously large magneto-Seebeck and Nernst effect in two polycrystalline samples of NbP, with a significantly reduced thermal conductivity from that of single-crystalline values and reasonably low resistivity, further indicating that magneto-thermoelectric effects are an area of major interest in WSMs. When comparing experimental data to theoretical models, we have determined that thermoelectric effects in NbP are incredibly sensitive to doping, altering not only the maximum values of thermoelectric transport properties but the temperatures at which these maxima occur. We conclude that changes in the Fermi temperature through doping can be used as a sensitive tuning mechanism for thermoelectric properties and the temperatures at which they are maximized. Finally, because NbP possesses the unique simultaneous presence of both a large magneto-Seebeck and Nernst effect, we propose a device which utilizes both thermopowers produced in the presence of a magnetic field. The resulting zT of such a device was found to be significantly higher than the zT observed by the individual thermoelectric effects and is greater than zT found in other competitive WSMs. We offer all of this as evidence for the viability of polycrystalline WSMs in thermoelectric devices.

The foregoing disclosure provides illustration and description, but is not intended to be exhaustive or to limit the embodiments to the precise form disclosed. Modifications and variations are possible in light of the above disclosure or may be acquired from practice of the embodiments.

As used herein, the term component is intended to be broadly construed as hardware, firmware, and/or a combination of hardware and software.

It will be apparent that systems and/or methods, described herein, may be implemented in different forms of hardware, firmware, or a combination of hardware and software. The actual specialized control hardware or software code used to implement these systems and/or methods is not limiting of the embodiments. Thus, the operation and behavior of the systems and/or methods were described herein without reference to specific software code—it being understood that software and hardware may be designed to implement the systems and/or methods based on the description herein.

Even though particular combinations of features are disclosed in the specification, these combinations are not intended to limit the disclosure of possible embodiments. In fact, many of these features may be combined in ways not specifically recited and/or disclosed in the specification.

No element, act, or instruction used herein should be construed as critical or essential unless explicitly described as such. Also, as used herein, the articles “a” and “an” are intended to include one or more items, and may be used interchangeably with “one or more.” Furthermore, as used herein, the term “set” is intended to include one or more items (e.g., related items, unrelated items, a combination of related and unrelated items, etc.), and may be used interchangeably with “one or more.” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

What is claimed is:

1. A thermoelectric energy generation system comprising:
a thermoelectric device made using a topological semimetal;
a heat source that heats a first end of the topological semimetal;
a heat sink that cools a second end of the topological semimetal that opposes the first end, wherein heating the first end and cooling the second end results in a temperature gradient (ΔT) between the first end and the second end, wherein the temperature gradient causes charge carriers to move in a first direction (x) from the first end to the second; and
a magnetic field generator that applies a magnetic field (B_{z}) to the topological semimetal in a second direction (z) that is perpendicular to the first direction (x), wherein characteristics of the topological semimetal cause a first portion of the charge carriers continue to move in the first direction (x), even in the presence of the magnetic field (B_{z}), wherein the magnetic field causes a second portion of the charge carriers to move in a third direction (y) that is perpendicular to the first direction (x) and to the second direction (z), wherein the temperature gradient (ΔT) and a longitudinal voltage (ΔVₓ) of the first portion of charge carriers creates a longitudinal thermopower (S_{xxz}), and wherein the temperature gradient (ΔT) and a transverse voltage (ΔV_{y}) of the second portion of the charge carriers create a transverse thermopower (S_{xyz}).

2. The thermoelectric energy generation system of claim 1, wherein the characteristics of the topological semimetal include a gapless energy band structure that causes the first portion of the charge carriers to continue to move in the first direction (x) even in the presence of the magnetic field (B_{z}).

3. The thermoelectric energy generation system of claim 1, wherein the topological semimetal is a Weyl semimetal or a Dirac semimetal.

4. The thermoelectric energy generation system of claim 1, wherein a shape of the topological semimetal is such that inverting coordinates of points in the topological semimetal does not result in an identical structure.

5. The thermoelectric energy generation system of claim 1, wherein the longitudinal voltage and the transverse voltage are created at the same or nearly the same time.

6. The thermoelectric energy generation system of claim 1, wherein the longitudinal thermopower and the transverse thermopower are of the same or similar order of magnitude.

7. A thermoelectric device comprising:
a topological semimetal that includes at least a first end, a second end that opposes the first end, and a gapless energy band structure,
wherein the first end is heated and the second end is cooled, wherein heating the first end and cooling the second end in a temperature gradient (ΔT) between the first end and the second end,
wherein the temperature gradient causes charge carriers to move in a first direction (x) from the first end to the second,
wherein a magnetic field (B_{z}) is applied to the topological semimetal in a second direction (z) that is perpendicular to the first direction (x),
wherein characteristics of the gapless energy band structure cause a first portion of the charge carriers to continue to move in the first direction (x), even in the presence of the magnetic field (B_{z}),
wherein the magnetic field causes a second portion of the charge carriers to move in a third direction (y) that is perpendicular to the first direction (x) and to the second direction (z),
wherein the temperature gradient (ΔT) and a longitudinal voltage (ΔVₓ) of the first portion of charge carriers create a longitudinal thermopower (S_{xxz}), and
wherein the temperature gradient (ΔT) and a transverse voltage (ΔV_{y}) of the second portion of the charge carriers create a transverse thermopower (S_{xyz}).

8. The thermoelectric device of claim 7, wherein the topological semimetal is a Weyl semimetal or a Dirac semimetal.

9. The thermoelectric device of claim 7, wherein a shape of the topological semimetal is a body-centered tetragonal structure.

10. The thermoelectric device of claim 7, wherein the longitudinal voltage and the transverse voltage are created at the same or nearly the same time.

11. A method for using a topological semimetal to generate a longitudinal thermopower and a transverse thermopower, the method comprising:
heating a first end of the topological semimetal;
cooling a second end of the topological semimetal, the second end opposing the first end, wherein heating the first end and cooling the second end causes a temperature gradient (ΔT) between the first end and the second end;
applying a magnetic field (B_{z}) to the topological semimetal in a second direction (z) that is perpendicular to the first direction (x), wherein characteristics of a gapless energy band structure of the topological semimetal cause a first portion of the charge carriers to continue to move in the first direction (x), even in the presence of the magnetic field (B_{z}), and wherein the magnetic field causes a second portion of the charge carriers to move in a third direction (y) that is perpendicular to the first direction (x) and to the second direction (z);
generating, based on temperature gradient (ΔT), a longitudinal voltage (ΔVₓ) for the first portion of charge carriers, wherein the longitudinal voltage (ΔVₓ) and the temperature gradient (ΔT) create a longitudinal thermopower (S_{xxz}); and
generating, based on temperature gradient (ΔT), a transverse voltage (ΔV_{y}) for the second portion of the charge carriers, wherein the transverse voltage (ΔV_{y}) and the temperature gradient (ΔT) create a transverse thermopower (S_{xyz}).

12. The method of claim 11, wherein the topological semimetal is a Weyl semimetal or a Dirac semimetal.

13. The method of claim 11, wherein a shape of the topological semimetal is such that inverting coordinates of points in the topological semimetal does not result in an identical structure.

14. The method of claim 11, wherein the longitudinal voltage and the transverse voltage are created at the same or nearly the same time.
